(19) United States
(12) Patent Application Publication
(10) Pub. No.: US 2023/0396218 A1
(43) Pub. Date: Dec. 7, 2023

(54) High millimeter-wave Frequency Gain-Boosting Power Amplifier with Differential Complex Neutralization Feedback Network

(71) Applicant: Georgia Tech Research Corporation, Atlanta, GA (US)

(72) Inventors: Hua Wang, Atlanta, GA (US); Tzu-Yuan Huang, Atlanta, GA (US); Mohamed Eleraky, Atlanta, GA (US); Yuqi Liu, Atlanta, GA (US)

(21) Appl. No.: 18/329,506

(22) Filed: Jun. 5, 2023

Related U.S. Application Data
(60) Provisional application No. 63/348,711, filed on Jun. 3, 2022.

(51) Int. Cl. H03F 1/02; H03F 3/45; H03F 3/21

(52) U.S. Cl. CPC H03F 1/0288; H03F 3/45183; H03F 3/211; H03F 2200/387; H03F 2200/06; H03F 2200/451

(57) ABSTRACT

An exemplary device with differential complex neutralization circuit and device structure are disclosed that can provide substantial device gain boosting over a wide bandwidth (BW) for an amplifier core, e.g., for low noise power amplifier, high frequency amplifier, power amplifier, and the like. The device structure includes neutralization capacitors with designed inductors for the collectors, bases, and capacitor feeding that substantially improve the device gain/stability over a wide bandwidth by absorbing the parasitic inductors of the routings/vias and the capacitors and minimizes the passive loss. At high mm-Wave, neutralization can be realized by overlapping metal traces in device layouts to achieve a device gain of greater than unity gain.

### RELATED APPLICATION

This U.S. application claims priority to, and the benefit of, U.S. Provisional Patent Application No. 63/348,711, filed Jun. 3, 2023, entitled “High millimeter-wave Frequency Gain-Boosting Power Amplifier with Differential Complex Neutralization Feedback Network,” which is incorporated by reference here in its entirety.

### BACKGROUND

Sub-terahertz (sub-THz) electronics such as D-band (110-170 GHz) can provide low atmospheric attenuation and massive available bandwidth to support the capacity and latency demands in 6G and next-generation radar systems.

D-band electronics and amplifiers are limited in device performance, especially for CMOS devices, in their support for high intrinsic device power gain at high mm-Wave. At high mm-Wave frequencies, the passive networks of the device can exhibit high passive losses, which can degrade the actual circuit-level power gain as well as the circuit output power and efficiency.

Most silicon devices exhibit insufficient unilateral gain (U) values at high mm-Wave for efficient power amplification. Existing high mm-Wave circuits currently uses single-ended metal traces in device layouts. Embedding techniques have been used in conjunction with such layouts to realize ˜4U device gain at one single frequency, with limitations on bandwidth (BW), stability, and input/output impedance.

There is a benefit to improving circuit design and topologies for high mm-Wave frequencies.

### SUMMARY

An exemplary device with a differential complex neutralization circuit and device structure are disclosed that can provide substantial device gain boosting over a wide bandwidth (BW) for an amplifier core, e.g., for low noise power amplifier, high-frequency amplifier, power amplifier, and the like. The device structure includes neutralization capacitors with judiciously designed inductors for the collectors, bases, and capacitor feeding that can substantially improve the device gain/stability over a wide bandwidth by absorbing the parasitic inductors of the routings/vias and the capacitors and minimizing the passive loss. At high mm-Wave, neutralization can be realized by overlapping metal traces in device layouts to achieve a device gain of U; otherwise, the routing traces for capacitive neutralization can contribute significant inductive parasitics and degrade the neutralization effectiveness.

To this end, at high mm-Wave frequencies, the high-order feedback can attain the maximum achievable gain greater than the unitary power gain (Gₘₐₓ>U) over a wide BW, and that can be co-optimized with the device layout to cover the BW of interest. The differential complex neutralization feedback can be implemented with coupler-based matching network to gain higher frequency mm-Wave gain-boosting power.

Indeed, the exemplary circuit and method can be used to boost the differential device gain to U and improve stability for various commercial applications (e.g., any class-AB biasing or load line matching to reduce the achievable gain).

In an aspect, an apparatus is disclosed comprising an amplifier core having a differential complex neutralization circuit configured to receive an input signal (e.g., mm-Wave signal) and generate an output signal having a device gain boosting over a wide bandwidth (BW) (e.g., wherein at the mm-Wave signal, the circuit having a device layout that includes high-order feedback that can attain Gmax>U over a wide BW that can be optimized (e.g., co-optimized) with the device layout to cover a pre-defined BW).

In some embodiments, the differential complex neutralization circuit includes a first amplifier having a first terminal, a second terminal, and a third terminal; a second amplifier having a fourth terminal, a fifth terminal, and a sixth terminal; a first transmission line coupling the first terminal of the first amplifier to the sixth terminal of the second amplifier through a first neutralization capacitor; and a second transmission line coupling the fourth terminal of the second amplifier to the third terminal of the first amplifier through a second neutralization capacitor.

In some embodiments, the third terminal of the first amplifier and the sixth terminal of the second amplifier couple to a ground plane through a first and second vias.

In some embodiments, the first terminal of the first amplifier and the fourth terminal of the second amplifier couple to respective power inputs through a third and fourth vias.

In some embodiments, the first neutralization capacitor, the second neutralization capacitor, the first amplifier, and the second amplifier are arranged in parallel orientation to one another.

In some embodiments, the first transmission line and the second transmission line cross over each other at a point of symmetry in each of the respective first transmission line and the second transmission line.

In some embodiments, the second terminal of the first amplifier and the fifth terminal of the second amplifier are coupled through an embedded transmission line.

In some embodiments, the apparatus further includes a second amplifier core that operatively couples to the amplifier core (e.g., through an inter-stage matching network), the second amplifier core having a second differential complex neutralization circuit.

In some embodiments, the apparatus further includes a second amplifier core that operatively couples to the amplifier core (e.g., through an inter-stage matching network), the second amplifier core not having the differential complex neutralization circuit.

In some embodiments, the apparatus further includes a coupler-based matching network that couples to outputs of the differential complex neutralization circuit of the amplifier core.

In some embodiments, the apparatus further includes a low-loss coupled line (CL) network that couples to outputs of the differential complex neutralization circuit of the amplifier core.

In some embodiments, the apparatus further includes an adaptive bias circuit configured to dynamically bias gate voltages of amplifier cores of the apparatus based on the input signal (e.g., input mm-Wave signal) (e.g., to improve linearity).

In some embodiments, the differential complex neutralization circuit is configured in a high-order neutralization network that can achieve multiple gain peaks over a wide BW (e.g., to provide substantial device gain boosting over a wide BW).

In some embodiments, the apparatus is configured as a power amplifier, a high-frequency amplifier, a low-noise amplifier, or a combination thereof.

In some embodiments, the apparatus is configured as a single-ended amplifier or a differential amplifier.

In some embodiments, the apparatus is employed in a telecommunication system (e.g., 5G, 6G, or other RF communication systems).

In some embodiments, the apparatus is employed in a RADAR system.

In some embodiments, the apparatus is employed in a medical instrument or an electronic test equipment.

In some embodiments, the apparatus is configured as a continuous mode coupler balun Doherty power amplifier.

### BRIEF DESCRIPTION OF THE DRAWINGS

The skilled person in the art will understand that the drawings described below are for illustration purposes only.

FIG. 1A shows an example amplifier with an amplifier core having a wideband complex neutralization structure in accordance with an illustrative embodiment.

FIG. 1B shows an example results of the EM simulation of the wideband complex neutralization circuit of FIG. 1A.

FIG. 2A shows a diagram illustrating a generalized model of the differential complex neutralization circuit in accordance with an illustrative embodiment.

FIG. 2B shows an implementation of the model of the differential complex neutralization circuit of FIG. 2A using transmission lines with pre-defined inductive characteristics.

FIGS. 2C and 2D show the implementation of the model of the differential complex neutralization circuit of FIG. 2B to an example device structure layout.

FIG. 3A shows a system design for the model of FIG. 2A and can be used as a systematic design approach to maximize the GBW of a device having the differential complex neutralization embedding network.

FIG. 3B shows an example result for different gains using the exemplary complex neutralization design in a CMOS device.

FIGS. 4A-4C show experimental results for a fabricated amplifier with the differential complex neutralization power amplifier core in accordance with an illustrative embodiment.

FIGS. 5A-5F show measurement and performance results of the amplifier of FIGS. 4A-4C in accordance with an illustrative embodiment.

FIGS. 6A-6E show a continuous mode coupler balun Doherty Power Amplifier (CCDPA) configured with the differential complex neutralization circuit in accordance with another illustrative embodiment.

FIGS. 7A-7C show measured results of the CCDPA device of FIGS. 6C and 6D in accordance with an illustrative embodiment.

### DETAILED SPECIFICATION

Some references, which may include various patents, patent applications, and publications, are cited in a reference list and discussed in the disclosure provided herein. The citation and/or discussion of such references is provided merely to clarify the description of the present disclosure and is not an admission that any such reference is “prior art” to any aspects of the present disclosure described herein. In terms of notation, “[n]” corresponds to the n^{th} reference in the list. All references cited and discussed in this specification are incorporated herein by reference in their entirety and to the same extent as if each reference was individually incorporated by reference.

Example Device with Wideband Complex Neutralization Structure

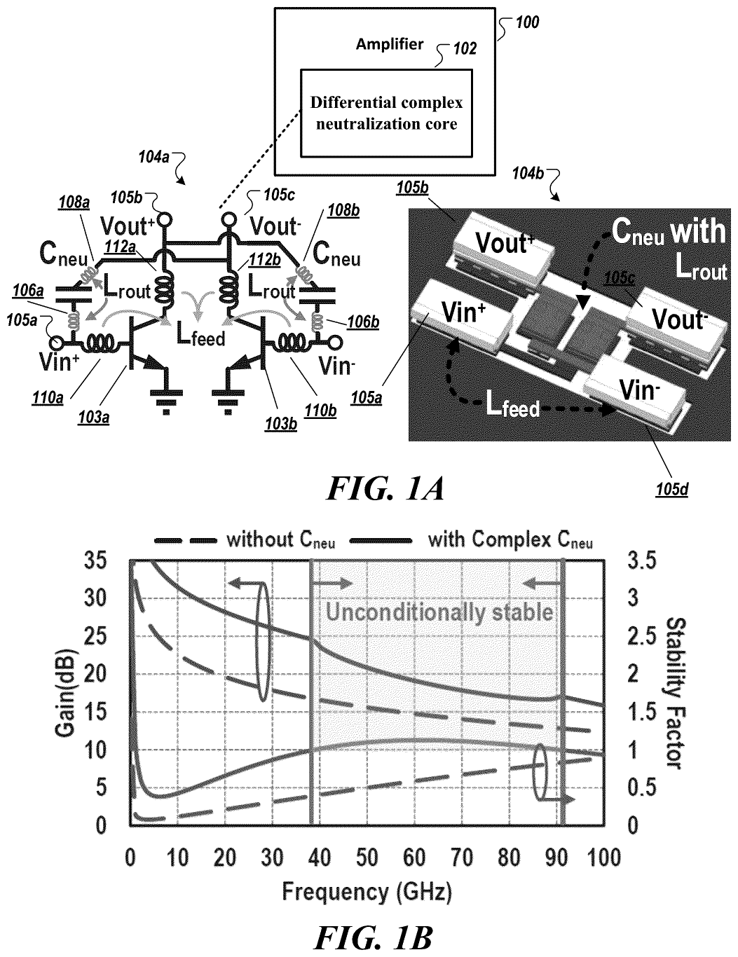

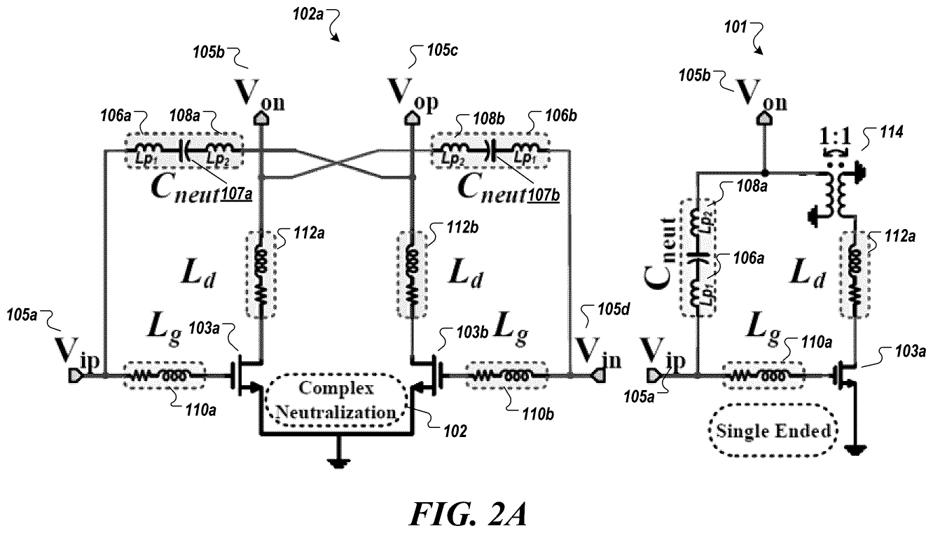

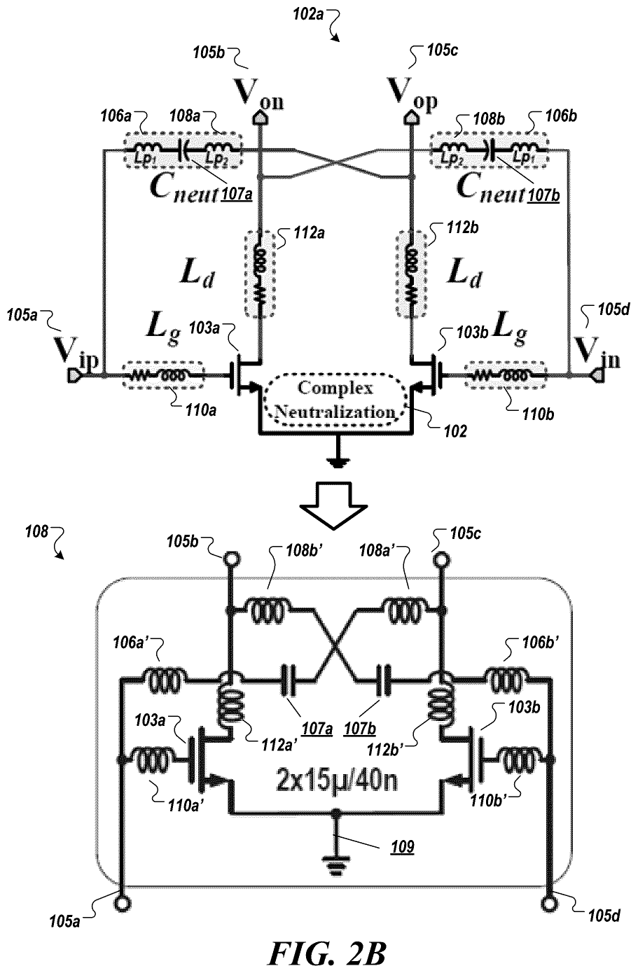

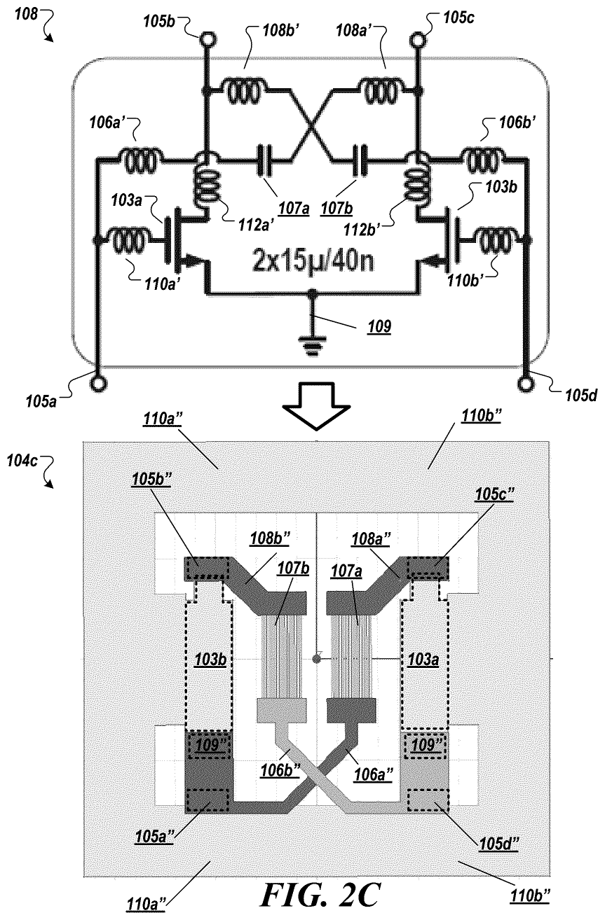

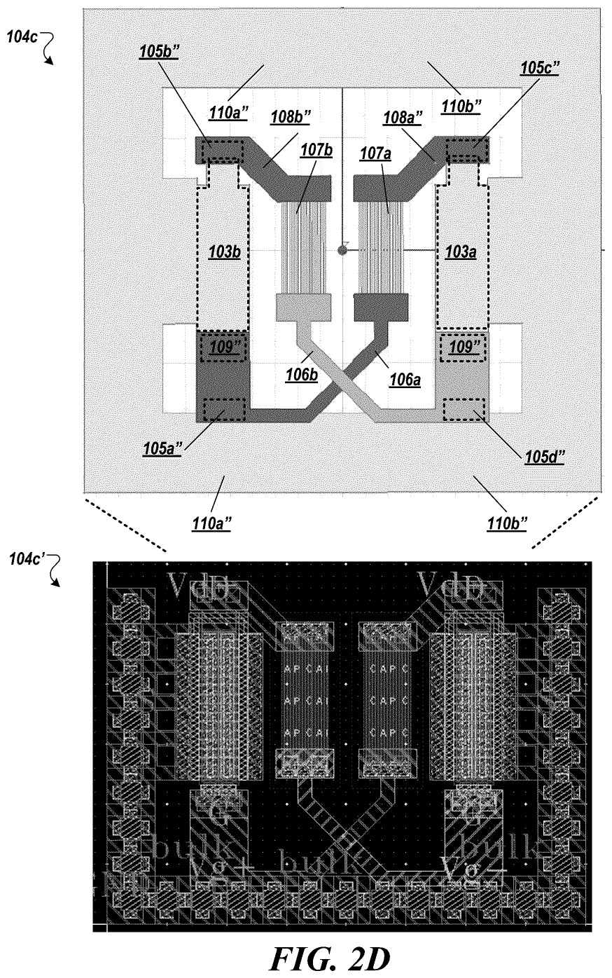

FIG. 1A shows an example amplifier 100 with an amplifier core 102 having a wideband complex neutralization structure in accordance with an illustrative embodiment. In FIG. 1A, the wideband complex neutralization circuit 104 (shown as 104a) and corresponding structure 104b (FIG. 2 shows a second example 104c) are shown. FIG. 1B shows an example results of the EM simulation of the wideband complex neutralization circuit 104a with structure/layout 104b. According to FIG. 1B, the complex neutralization structure can achieve a “double-peak” gain boosting with >3.8 dB Gₘₐₓ enhancement and maintains the unconditional stability for 37-91 GHz. Indeed, the exemplary high-order complex neutralization circuit can achieve wideband device gain, high output power, and stability enhancement at high mm-Wave and support wideband amplifications.

As shown herein, the term “amplifier core” (also refer to herein as “PA”) refers to the semiconductor structure in an integrated circuit or fabricated device that performs the amplification of an input voltage or input current. The exemplary differential amplifier core with complex, neutralization circuit can be implemented in various types of amplifier topologies, including power amplifiers, high-frequency amplifiers, and low-noise amplifiers. It is suitable for any frequency range of operations and, in a preferred embodiment, can be employed in sub-terahertz (sub-THz) electronics such as next-generation 5G-, 6G-mmWave phased-array communication applications, RADAR, or other wide-band high-frequency amplifier applications. The device can be configured for single-ended or differential operations.

The amplifier core can be implemented in any process, e.g., 800 nm, 600 nm, 350 nm, 250 nm, 180 nm, 130 nm, 90 nm, 65 nm, 45 nm, 32 nm, 22 nm, 14 nm, 10 nm, 7 nm, 5 nm, 3 nm, etc. In some embodiments, the amplifier core can be implemented in a fabrication process greater than 800 nm. In some embodiments, the amplifier core can be implemented in a fabrication process less than 3 nm.

Example Circuit Model and Layout for the Differential Complex Differential Circuit

FIG. 2A shows a diagram illustrating a generalized model 102a of the differential complex neutralization circuit 102 (for a set of amplifiers 103a, 103b having terminals 105a, 105b, 105c, 105d) in accordance with an illustrative embodiment. FIG. 2B shows an implementation of the model of the differential complex neutralization circuit of FIG. 2A using transmission lines with pre-defined inductive characteristics. FIG. 2C shows the implementation of the model of the differential complex neutralization circuit of FIG. 2B to an example device structure layout. FIG. 2D shows the device structure layout of FIG. 2C in the EM software tool which further shows the different layers.

In FIG. 2A, the generalized model 102a of the differential complex neutralization circuit 102 shows the device routing and via inductances and neutralization capacitor's self-inductances 107 being combined and modeled by parasitic inductors L_{P} (shown as “Lₚ₁” 106a, 106b and “Lₑ” 108a, 108b). The embedding network includes a series gate inductance L_{g} (110a, 110b) and a series drain inductance L_{d} (112a, 112b).

In addition, the finite quality factors of the passive elements are modeled; thus, the transistor gate and drain terminals can be independently biased for optimum device operation. FIG. 2A also shows the equivalent half-circuit 101 of circuit 102. In circuit 101, the cross-coupled connection is shown modeled as a one-to-one transformer 114 with opposite polarity to capture the opposite current/voltage polarities in the differential transistor pair.

In FIG. 2B the parasitic inductors Lₚ₁ (106a, 106b) and Lₚ₂ (108a, 108b) of the neutralization capacitors (107a, 107b) are shown implemented as transmission lines (106a′, 106b′, 108a′, and 108b′). In addition, the series gate inductance L_{g} (110a, 110b) and series drain inductance L_{d} (112a, 112b) are shown also implemented as transmission lines (110a′, 110b′, 112a′, and 112b′).

FIG. 2C shows the implementation of the model of the differential complex neutralization circuit of FIG. 2B to an example device structure layout. FIG. 2D shows the device structure layout of FIG. 2C in the EM software tool, which further shows the different layers. In FIG. 2C, the transmission lines 108a′, 108b′ (and vias) of the parasitic inductors Lₚ₂ (108a, 108b) are each implemented as a symmetrical bend line 108a″ and 108b″ having value Lₚ₂ and connects, through the neutralization capacitor 107a, 107b, to the transmission lines 106a′, 106b′ (and vias) of the parasitic inductors Lₚ₁ (106a, 106b) also implemented as symmetrical bend lines 106a″ and 106b″ to have value Lₚ₁. In the example shown in FIG. 2C, the transmission lines 106a″, 106b″ cross over each other. In other embodiments, the transmission lines 108a″, 108b″ would cross over each other. To minimize other parasitic inductances, the transmission lines 108a″, 108b″ connects to the terminals for Vₒₙ and Vₒₚ (105b′ and 105c′) through vias to another plane having the Vd+ and Vd− routing (see FIG. 2D), and the transmission lines 106a″, 106b″ connects to the terminals for Vᵢₚ and Vᵢₙ (105a′ and 105d′) through vias to another plane having the Vg+ and Vg− routing (see FIG. 2D).

The neutralization capacitors 107a, 107b are respectively routed in parallel orientation to the differential amplifiers 103a, 103b, the sources of the amplifiers 103a, 103b connecting to ground (G) 109 through vias (109″) to the ground plane, the drains of the amplifiers 103a, 103b connecting to power Vₒₙ and Vₒₚ (105b′ and 105c′) through vias (105b″ and 105c″) to a power plane. The gate of the amplifiers 103a, 103b are connected to gate inductance L_{g} (110a, 110b) through embeddings 110a″ and 110b″ that surrounds the amplifier 103a, 103b and neutralization capacitors 107a, 107b.

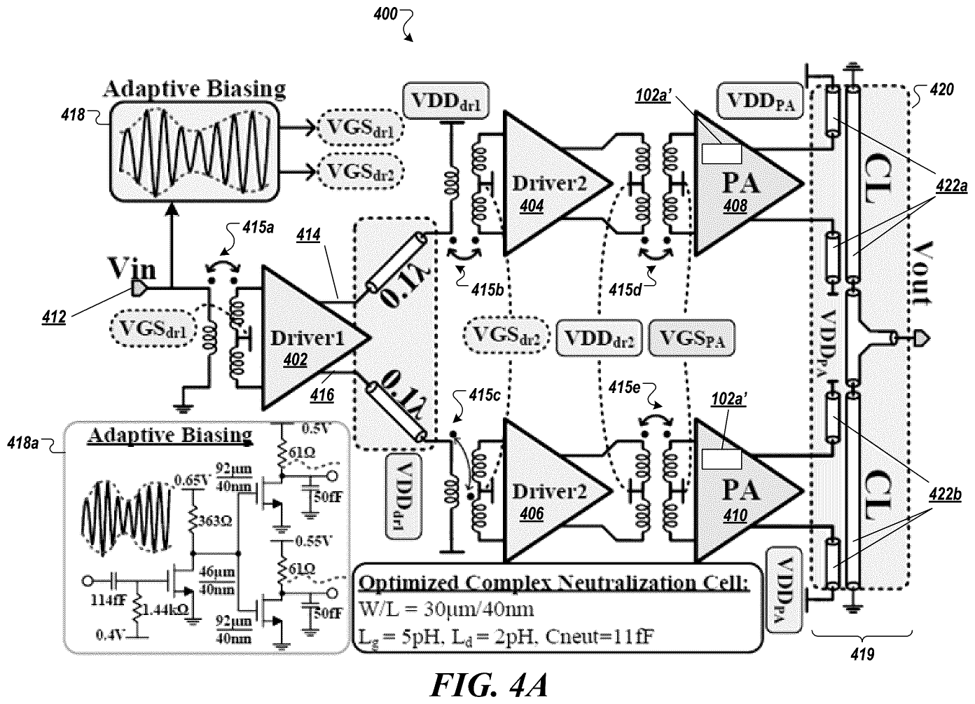

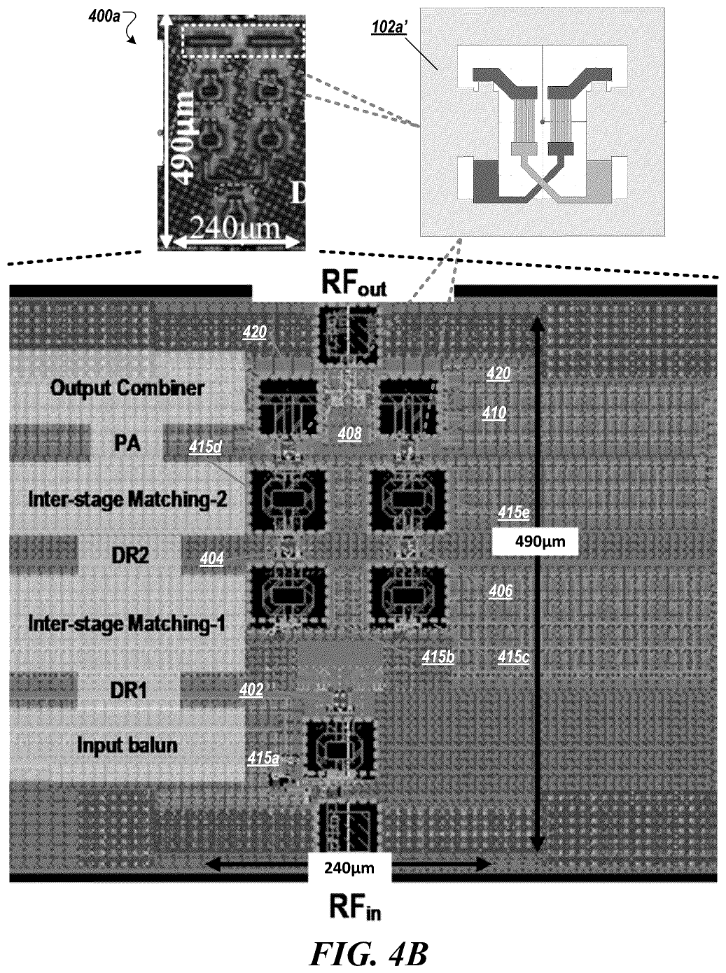

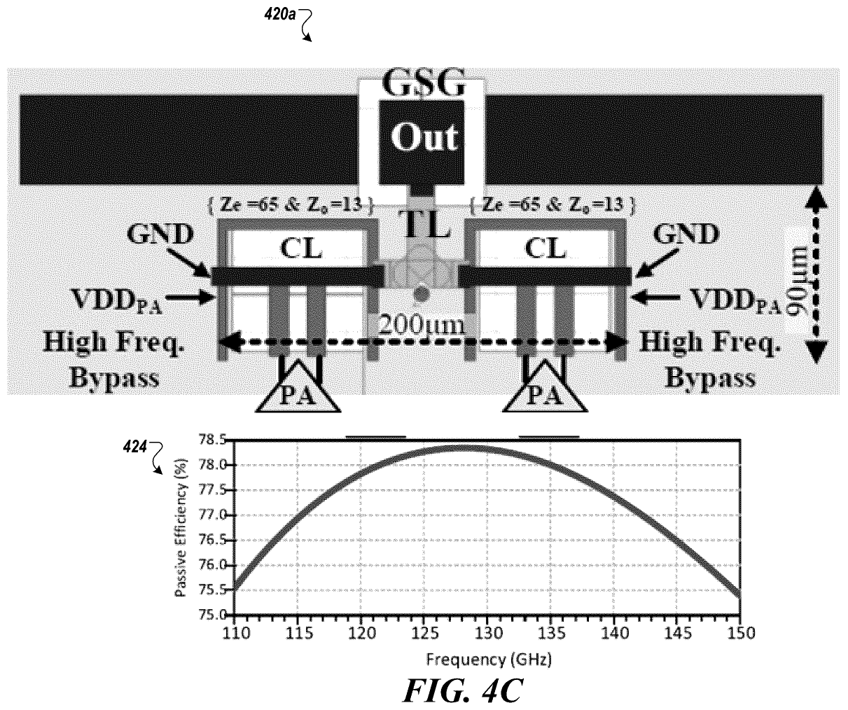

Indeed, the exemplary complex neutralization circuit (FIGS. 2A, 2B and 2C, 2D) inherently absorbs the parasitic inductors of the routings/vias and the capacitors and minimizes the passive loss (see FIGS. 4A-4C).

Design Considerations. The device level 3-dB BW of the differential complex neutralization circuit of FIG. 2 can be defined as the bandwidth (BW) over which the device gain exceeds 2U; this device level 3-db BW is the 3-dB drop from the theoretically maximum device gain Gₘₐₓ of 4U. Therefore, a device GBW (gain bandwidth) product can be formulated as the device power gain integrated over the 3-dB BW. To this end, the device GBW can be used to guide the embedding network design and maximize the resulting device GBW.

The maximum available power gain Gₘₐ of a two-port network can be expressed per Equation 1.

$$\frac{{G}_{ma}}{U} = {\vert \frac{A - {G}_{ma}}{A - 1} \vert}^{2} \qquad ( Eq . 1 )$$

In Equation 1, the unitary gain U for the two-port network is independent of the embedding network, and A can be defined per Equation 2.

$$A = \frac{{Y}_{21}}{{Y}_{12}} = \frac{{Z}_{21}}{{Z}_{12}} = \frac{{S}_{21}}{{S}_{12}} \qquad ( Eq . 2 )$$

The parameter A can be selected to boost the device Gₘₐ to Gₘₐₓ=4U by the desired linear, lossless, and reciprocal embedding networks W. There are other embedding network solutions in practice that can be used, and Equation 1 does not show any implication on the bandwidth.

Discussion Differential amplifier cores can have capacitive neutralization that can provide for wideband frequency configuration, reverse isolation, and stability enhancement. Better isolation also decouples the input/output to ease wideband matching. At high mm-Wave, the idealized broadband capacitive neutralization of the differential amplifier can be affected by substantial parasitics, for example, the parasitic inductors within the physical capacitors, metal routings, and via-stacks of the amplifier core. FIG. 2C shows an example of the wideband complex neutralization structure with a neutralization capacitors (Cₙₑᵤ) device layout having judiciously designed inductors for the collectors-, bases-, and capacitor-feeding that substantially improve the device gain/stability over the wide bandwidth of the differential amplifier cores. This complex neutralization structure can intrinsically absorb the parasitic inductors of the routings/vias and the capacitors and minimizes the passive loss.

While most III-V PAs are single-ended, differential PAs have benefits for wideband designs. First, they enable capacitive neutralization that, unlike narrow-band embedding networks [7′], achieves wideband PA device gain, reverse isolation, and stability enhancement. Better isolation also decouples the input/output to ease wideband matching.

Secondly, differential PAs can use distributed or lumped baluns with center-tap or AC-grounded ports for DC feedings. This can obviate large biasing resistors in single-ended PAs and separates DC biasing from mm-Wave signal paths, which can minimize bias-related memory effects and enables GHz wideband modulations [8′]. Finally, differential PAs inherently double the output power with differential power combining.

For differential amplifiers, popular differential broadband neutralization designs often employ series capacitors. However, at high mm-Wave, ideal broadband capacitive neutralization ceases to exist due to substantial parasitics, e.g., parasitic inductors within the physical capacitors, metal routings, and via-stacks, which together largely negate the neutralization efficacy over broadband frequency, e.g., 35-100 GHz. The exemplary layout design of the exemplary complex neutralization structure sufficiently minimizes the parasitic loss to allow for capacitive neutralization operation at the broadband frequency.

Example Design Operation

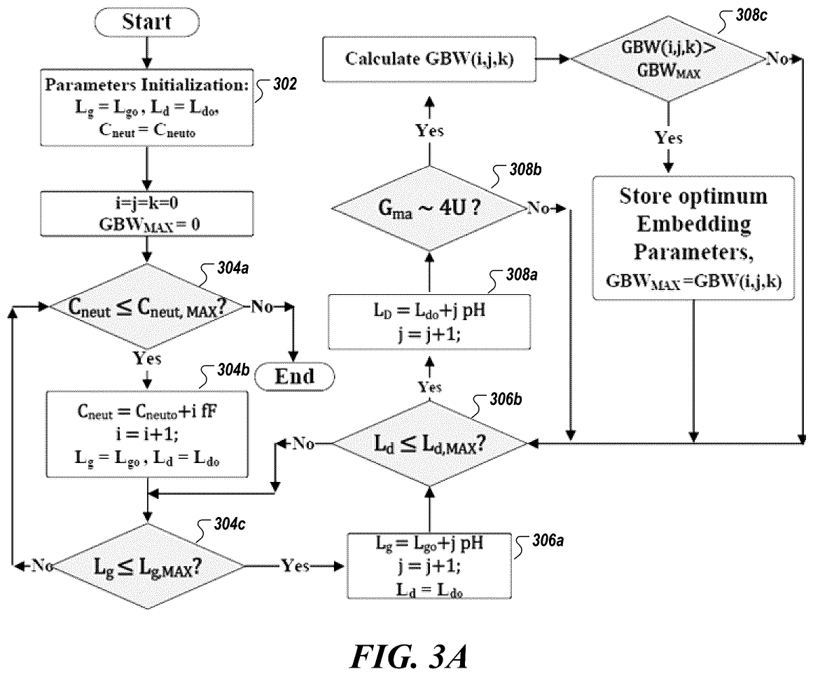

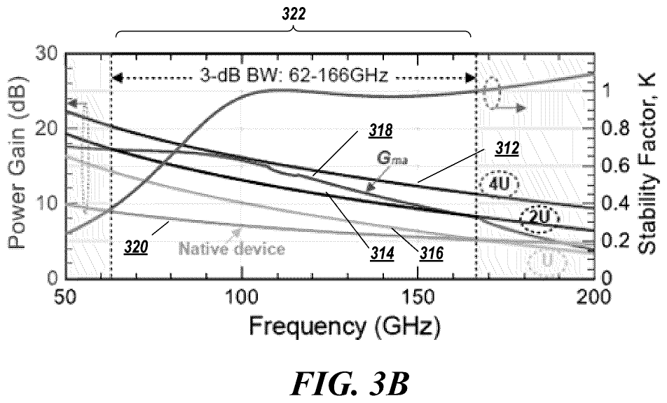

FIG. 3A show a system design for the model of FIG. 2A and can be used as a systematic design approach to maximize the GBW of a device having differential complex neutralization embedding network. First, the Y-parameters (Equation 2) of the exemplary amplifier core with the embedding network can be analyzed using the equivalent half-circuit in FIG. 2A.

Then, by applying the practical values of the inductors and capacitances for the given technology, a parameter sweep for the embedding networks can be performed. Next, for each embedding network achieving peak Gₘₐ≈Gₘₐₓ, the GBW can be calculated. The corresponding embedding network design can be updated to track the highest GBW.

Specifically, in FIG. 3A, the parameters L_{g}, L_{d}, and Cₙₑᵤₜ can be initialized (302). For a loop i (shown as 304a, 304b, 304c), while Cₙₑᵤₜ is less than C_{neut,max} (304a), and while L_{g} is less than L_{g,max} (304c), the Cₙₑᵤₜ can be updated (304b) as Cₙₑᵤₜ=Cₙₑᵤₜₒ+i Ff. Within loop i, if L_{g} is less than L_{g,max} (304c), L_{g} can be updated in a loop j (shown as 306a, 306c, 304c) as L_{g}=L_{go}+j pH (306a) while L_{d} is less than L_{d,max} (306b). And, within loop j if L_{d} is less than L_{d,max} (306b), L_{d} can be updated (308a) until Gₘₐ is at a predefined gain (e.g., 4U) (308b) and the current value for GBW(i,j,k) (308c) is greater than the prior value for GBWₘₐₓ.

Indeed, the exemplary embedding network design methodology can be applied for any general embedding networks, for any given device technologies, and any carrier frequencies. Also, it can be used to compare different technologies and gain boosting techniques.

FIG. 3B shows example results for gains 4U (312), 2U (314), U (316), and the maximum available gain Gₘₐ (318) using the exemplary complex neutralization design as compared to a native device gain (320) in a CMOS SOI device. FIG. 3B shows the plots of the power gain (in dB) over frequency (in GHz). The results shows the design methodology as applied on the GlobalFoundries 45RFSOI process to optimize the complex neutralization embedding network design for D-band amplifiers (shown over frequencies 322). As shown in FIG. 3B, the high gain (Gₘₐ>2U) is achieved over a large bandwidth of 62-162 GHz, supporting wideband circuits at D-band. Different from [4′] which can achieve Gₘₐ˜4U only at limited bandwidth, the complex neutralization networks with physical and lossy elements can achieve high gain (Gₘₐ>2U) over an extended bandwidth.

Example Power Amplifier with Differential Complex Neutralization Power Amplifier Core

FIGS. 4A-4C show experimental results for a fabricated amplifier with the differential complex neutralization power amplifier core in accordance with an illustrative embodiment. In FIG. 4A, a schematic of an amplifier 100 (shown as Power Amplifier 400) is shown configured as a three-stage power amplifier having a first-stage driver (shown as “Driver 1” 402), a second-stage driver (shown as “Driver 2” 404, 406), and a third stage power amplifier (shown as “PA” 408, 410) in which the third stage power amplifier (408, 410) is implemented with the differential complex neutralization power amplifier core 102a (shown as 102a′).

The differential complex neutralization power amplifier core 102a′ employs routing inductive parasitics L_{g}, L_{d}, and L_{P} with the feedback capacitors Cₙₑᵤₜ, as described in relation to those shown in FIGS. 2A-2D and 3A-3B to form a high-order neutralization network that can facilitate wideband and high gain boosting.

In FIG. 4A, the first stage driver 402 receives an input voltage at input terminal 412 through an input matching network 415a to provide differential outputs 414, 416 to two separate paths (differential paths) that each includes the Driver-2 stage (having 404, 406) and the PA output stage (having 408, 410). The second stage driver 404, 406 connects to the first stage driver 402 through an interstage matching network 415b, 415c, and the third stage power amplifier core 408, 410 connects to the second stage driver 404, 406 through an interstage matching network 415d, 415e. The third stage power amplifier core 408, 410 has a PA output network that includes a low-loss coupled line (CL) network 420 that can match the output load (e.g., 50Ω load) to a PA's optimum load-pull load [5] in which the CL structure 422a, 422b accurately captures both electric (capacitive) and magnetic (inductive) coupling within a compact model, e.g., as compared to a lumped transformer.

In addition, in FIG. 4A, the first stage driver 402 is configured to be adaptively biased 418 via an on-chip adaptive biasing circuit (shown as 418a). The on-chip adaptive biasing circuit 418 can dynamically bias the gate voltages of Driver-1/Driver-2 stages (404, 406 and 408, 410) based on the PA input signal level to improve linearity. The front gate biasing 418 through the transformer center-taps can support high modulation speed, which is higher than a back gate adaptive biasing as, for example, described in [6′],

FIG. 4B shows the amplifier chip 400 (shown as 400a) having the power amplifier core 102a′ implemented in a 45 nm-RFSOI having a core size of 490 μm×240 μm. The input matching network 415a and the matching network 415b, 415c, 415d, 415e are implemented as baluns.

In the example of FIG. 4A, the amplifier 400 is configured to operate in two modes of operation (high gain (H_{G}) and high-linearity (H_{L})) based on the operation of an adaptive biasing circuit (H_{G} mode=adaptive biasing off; H_{L} mode=adaptive biasing on). The H_{G} mode was observed to have a power gain of 21.7 dB with a gain compression parameter to the output power (OP_{1 dB}/Pₛₐₜ) of 8.2/11.9 dBm, respectively, and a power-added efficiency (PAE) of 14.6%. Activating the adaptive bias 418 enabled the H_{L} mode in which the OP_{1 dB} is boosted to reach near the Pₛₐₜ of 11.85 dBm with the PAE of 15%. The PA 400 can accommodate 64-QAM at a high data rate of 27 Gb/s with an EVM of −24.85 dB, while also exhibiting the state-of-the-art ACPR in the D-band. To the authors' knowledge, this is the most efficient-yet-linear operation at D-band with the highest reported PAE at OP_{1 dB} in a CMOS device.

CL Network with Power Combiner. FIG. 4C shows the 3D EM model of the CL-based PA output network 420 (shown as 420a) having a matching- and power combiner. The combined matching and power combiner 420a can be implemented as a zero-phase two-way power combiner, which is optimized to minimize the area overhead and loss within the CL network. Simulation results, in plot 424, show the circuit can achieve high passive efficiency. The compact CL shows a peak passive efficiency of 78.4% at around 130 GHz, illustrating high output power and efficiency of the PA 400 at D-band operation.

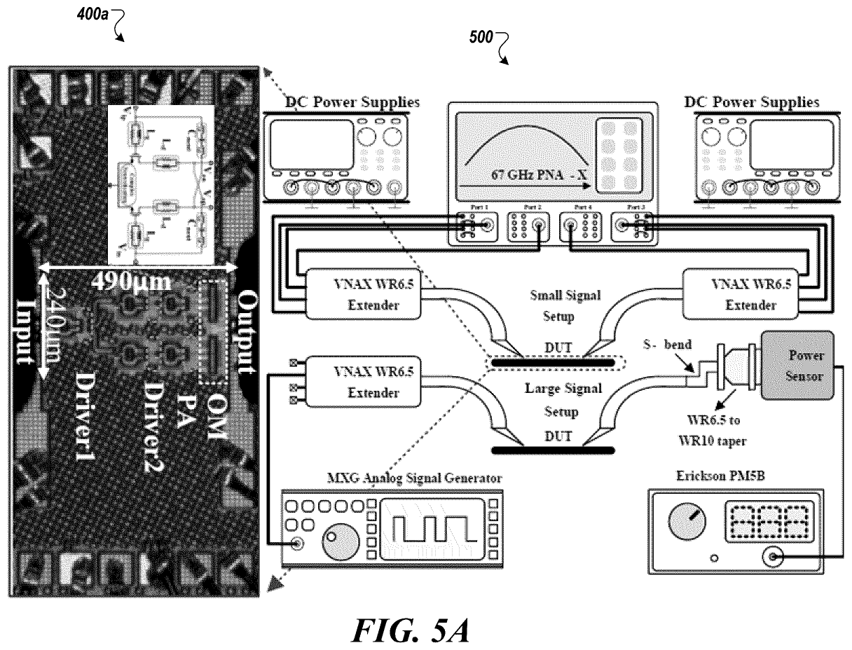

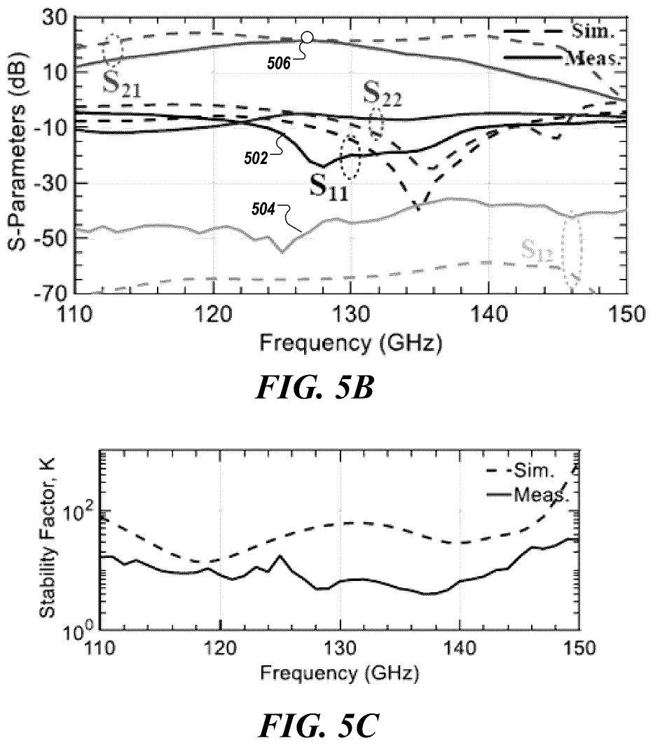

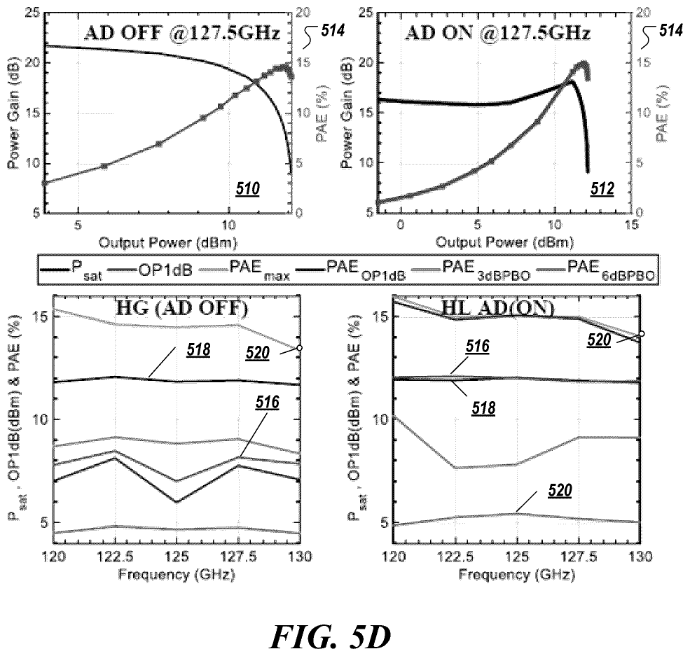

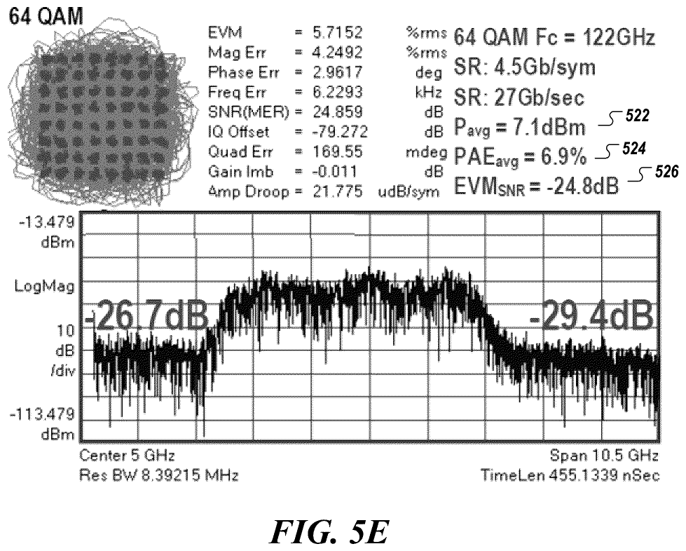

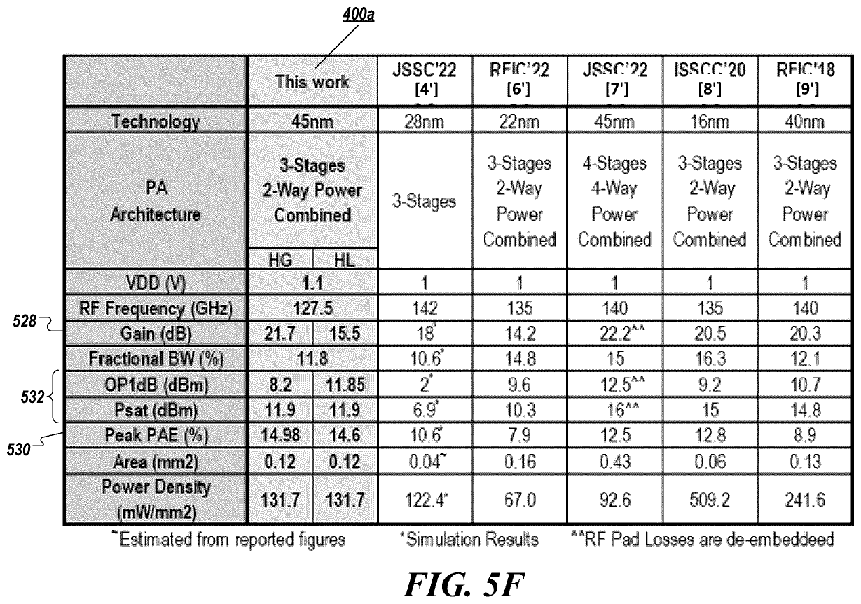

MEASUREMENT RESULTS. FIGS. 5A-5F show measurement and performance results of the amplifier of FIGS. 4A-4C in accordance with an illustrative embodiment.

In FIG. 5A, the PA chip 400a occupies a compact core size of 490 μm×240 μm. FIG. 5A also shows the small-signal measurement setup 500 employed for the measurement. As shown in FIG. 5A, chip 400a was measured by direct probing using a set of 100 μm-pitch waveguide GSG probes. A calibration substrate was used for de-embedding the GSG probe tips as the reference plane. The PA output stage uses a 1.1V supply, while Driver-1/Driver-2 stages (402, 404, 4060 use a 0.7V supply.

FIG. 5B shows the measured and simulated small-signal S-parameters of the PA 400a for D-band operation. The measurements show the PA 400a achieved a 21.7 dB peak power gain (506) at 127.5 GHz and a 3-dB bandwidth of 15 GHz (117-132 GHz). Differences in the measured results to the simulations likely are due to underestimation of device parasitics and the dummy fillings. The measured S₁₁ (502) is below −10 dB from 123-138 GHz, and the measured S₁₂ (504) is below −35 dB over the whole band.

FIG. 5C shows the measured and simulated stability factor K of the PA, which has a measurement of above a value of 5, showing unconditional stability. FIG. 5A shows the large signal measurement setup. As shown in FIG. 5A, direct probing was used with a calibration reference plane to the GSG probe tips. An Erickson PM5B power meter was used for the PA's output power measurements.

FIG. 5D shows the measured power gain (PG) and PAE for the chip 400a at the different frequencies as a function of output power for large-signal measurements for the H_{G} and H_{L} modes (510, 512) versus output power over frequencies. In FIG. 5D, at 127.5 GHz, with the adaptive bias off/on (H_{G}/H_{L}) (510, 512), the measured peak PAE (514) reached 14.6% and 15%, respectively, with the same saturated output power Pₛₐₜ of 11.9 dBm. However, the PA OP_{1 dB} (516) increased from 8.2 dBm to 11.85 dBm with the use of adaptive biasing. With the adaptive biasing off (on), the measured Pₛₐₜ (518), OP_{1 dB} (516), and PAE (520) are better than 11.7 (11.7) dBm, 7.6 (11.8) dBm, and 13 (14) %, respectively over 120 GHz-130 GHz. Indeed, over this wide frequency range, the adaptive biasing reduced the difference of OP_{1 dB} and Pₛₐₜ to <0.2 dB, while the PAE at 3-dB/6-dB power back off (PBO) was better than 7.7%/4.8%, showing efficient-yet-linear D-band PA performance.

The chip 400a was also characterized by a single carrier 64-QAM. Because of the lack of a bandpass filter at the PA's center frequency, a frequency of 122 GHz was utilized for testing purposes. FIG. 5E shows, using a modulation bandwidth of 4.5G Sym/s (27 Gb/s), the PA 400a achieved an average output power, P_{avg}, of 7.1 dBm (522), an average PAE of 6.9% (524), and a relative error vector magnitude (EVMrms) of −24.85 dB (526). Assuming a flat power spectral density at the adjacent channels, the Adjacent Channel Power Ratio (ACPR) can be estimated from the measured value.

FIG. 5F shows a table with a comparison the PA chip 400a and other state-of-the-art D-band PAs. With optimized complex neutralization for device gain boosting, the PA chip 400a shows the highest gain per stage (528), the highest PAE (530), and the best AM-AM linearity (difference of OP_{1 dB} and Pₛₐₜ) (532).

Continuous Mode Coupler Balun Doherty PA (CCDPA) with Differential Complex Neutralization Core

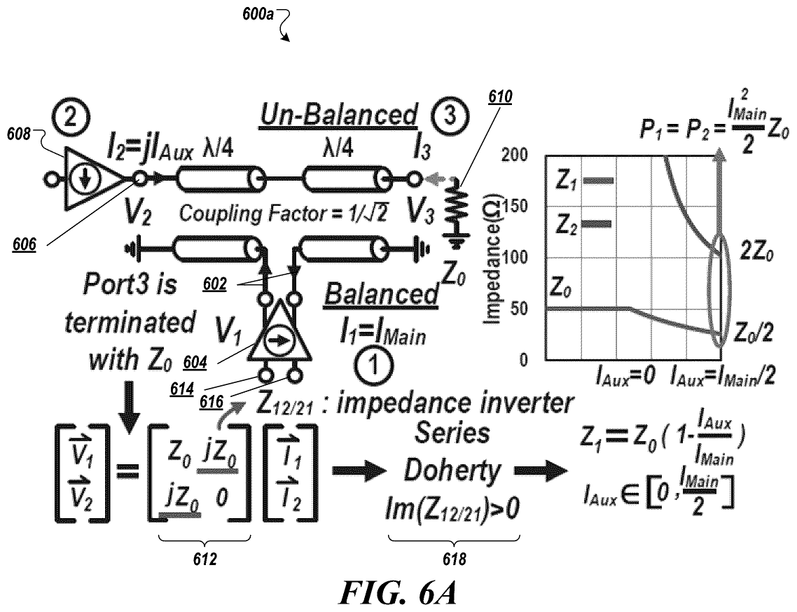

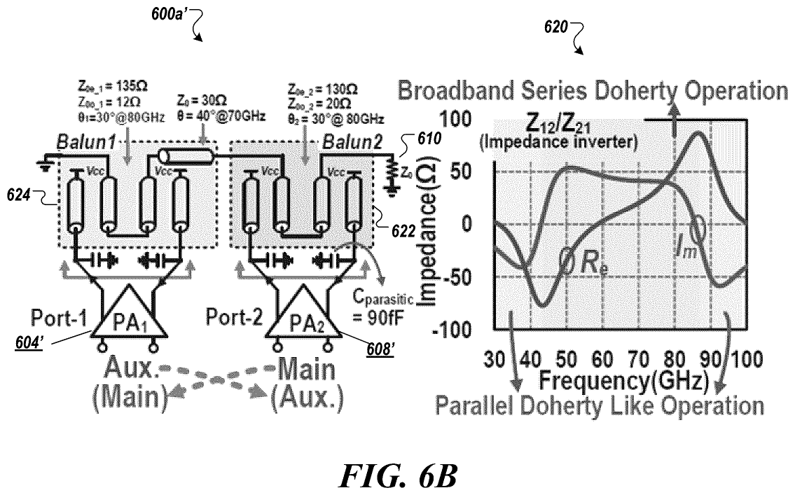

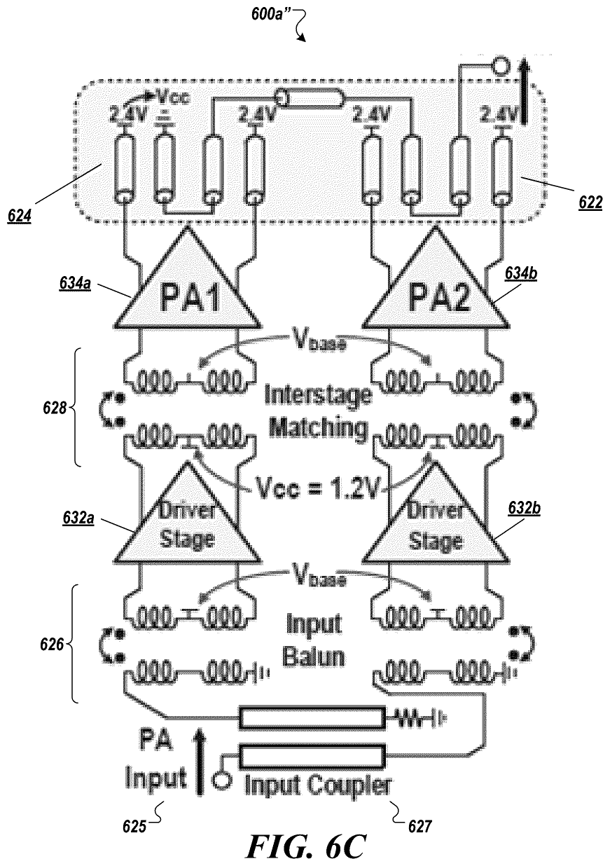

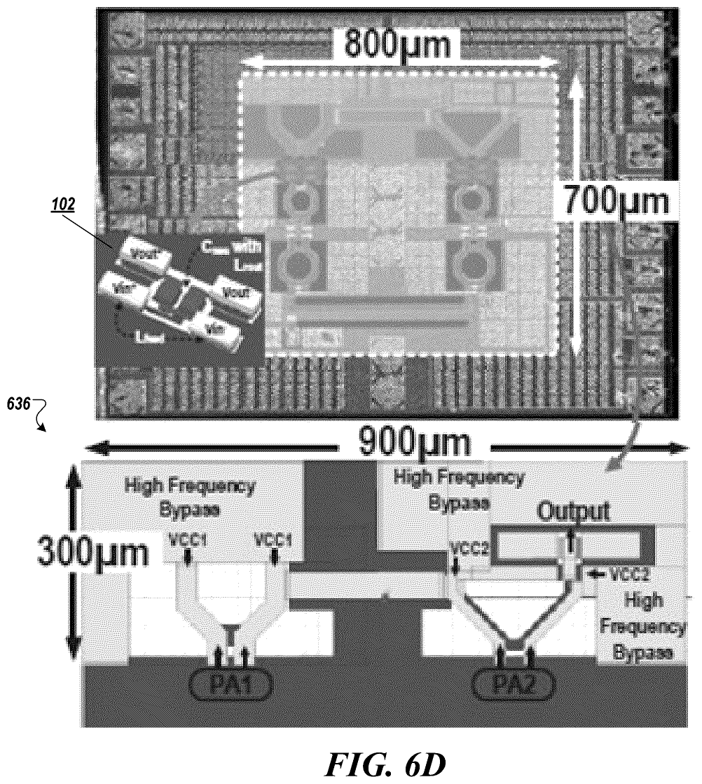

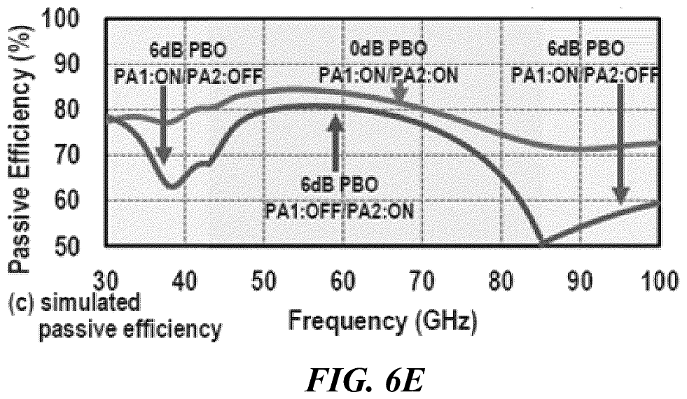

In another second example, FIGS. 6A-6E show a continuous mode coupler balun Doherty Power Amplifier 600 (CCDPA) configured with the differential complex neutralization circuit 102 in accordance with another illustrative embodiment.

The CCDPA 600 is configured for high peak/PBO efficiency operation with 3:1 bandwidth simultaneously over Ka-, V- and W-bands by differential complex neutralization and continuous mode coupler balun Doherty output network in 250 nm InP. The CCDPA 600 with the differential complex neutralization technique can achieve broadband double-peak gain/reverse isolation improvement. At 60 GHz, an example CCDPA 600 (referenced as 600a) was observed to achieve 27.3% peak PAE with 21.5 dBm Pₛₐₜ, 22.9% PAE at 19.3 dBm OP_{1 dB}, and 19.1% PAE at 15.5 dBm (6 dB PBO).

The CCDPA 600a also includes an active load modulation network using two coupler baluns in series connection, which, together with Main/Auxiliary (Aux) PA role exchange, can achieve Doherty-like back-off efficiency enhancement over a 3:1 bandwidth. Distinct from the LMBA PA with 90° coupler, our CCDPA and its coupler balun active modulation network offer several benefits, including differential operation, equal Main/Aux PA weighting, and no inherent early gain compression. Each CCDPA Main/Aux path consists of a two-stage common emitter (CE) PA for optimal power gain and efficiency.

Overall, the InP CCDPA achieved 18.9-22.6 dBm Pₛₐₜ, 14.7-29.3% peak PAE, and 8.2-19.2% 6 dB PBO PAE over 35-100 GHz, showing ×1.08−×1.4/×2.16−×2.86 dB PBO efficiency boost ratio compared to normalized ideal class-B/class-A PA.

The CCDPA 600a has superior wideband high peak/PBO efficiency and outperforms the state-of-the-art wideband InP PA, having 18.9-22.6 dBm Psat, 14.7-29.3% peak PAE and 8.2-19.2% 6 dB PBO PAE supporting 3 Gbps 64QAM signal over 35-100 GHz operation.

The CCDPA 600a can be employed in 5G⁺ communication, RADAR, and other wireless applications.

FIGS. 6A and 6B show the CCDPA 600 (shown as 600a) employing a modified CCDPA topology that exploits all four ports of a coupler balun for broadband active load modulation and PA PBO efficiency enhancement. In FIG. 6A, the input 602 to the coupler balun is driven by a differential PA₁ (604); the isolation port (606) is driven by PA₂ (608); the unbalanced ports are terminated with the 50Ω antenna load (610). The corresponding 2-port Z-matrix (612) can be derived, and Z_{12/21} can act as an impedance inverter. By correctly exciting Port1/2 (614, 616), the corresponding active load modulation is achieved, and it can be recognized as a series Doherty operation (618) with Iₘ (Z_{12/21})>0. Indeed, FIG. 6A shows that differential driving impedance Z₁ is modulated by the output current of PA₂. When I_{Aux}=0 and PA₂ is off, Z₁=Z₀ as no modulation is occurring. When I_{Aux}=(1/2)I_{Main}, Z₁=(1/2)×Z₀ can achieve the desired series Doherty active load modulation.

FIG. 6B shows a fully differential CCDPA 600a (shown as 600a′) and its simulated Z_{12//21} results 620. In the fully differential PA configuration 600a′, the PA₂ 608 (shown as 608′) is realized using a second differential PA also with an output coupler balun 622, while the first differential PA₁ 604 (shown as 604′) is connected to an output coupler balun 624. The coupler baluns' electrical lengths are reduced from 90° to only 30° for compact layout after absorbing the PA device output capacitances. Indeed, the coupler balun (622, 624) inherently supports differential PA operations with wideband capacitive neutralization and impedance transformation [11]-[13] for both peak and 6 dB PBO.

FIG. 6C shows an example implementation of the CCDPA device 600a (shown as 600a″) as described in relation to FIGS. 6A and 6B. FIG. 6D shows a die photo of a CCDPA 600a″ implemented in Teledyne 250 nm InP process having the differential complex neutralization circuit 102 and the coupler balun based output network with Doherty-like active load modulation of FIG. 6B. FIG. 6E shows simulations of the passive efficiency of the coupler balun output based network over 30-100 GHz.

In FIG. 6C, the single-ended input 625 is split to two differential quadrature signals by an input 90° coupler 627 and two transformer baluns (shown as 626). Each Main/Aux PA path contains a two-stage transformer-coupled differential common-emitter PA (shown as 630a, 630b, 632a, 632b) for optimal power gain and efficiency.

The complex neutralization circuit (e.g., 102) is implemented in both the driver- and power stage to boost the device gain and isolation. The coupler balun Doherty networks (622, 624) were employed to provide wideband active load modulation and to deliver the combined power to a single-ended son load.

The InP PA chip microphotograph is shown in FIG. 6D using a Teledyne 250 nm InP HBT process. The compact core area is 800 μm×700 μm. Full 3D-EM model of the coupler balun Doherty networks (622, 624) is shown in diagram 636. By leveraging broadband active modulation and Main/Aux PA role-exchange, the CCDPA 600a″ was observed to achieve efficient active load modulation over 35-100 GHz with a low-loss of >71.3% passive efficiency at 0 dB PBO (FIG. 6E).

The CCDPA device 600a″ can be configured, in an example, as a 35-100 GHz continuous mode coupler balun Doherty PA. The CCDPA employs the active load modulation network using two coupler baluns 626, 628 in series connection, which, together with Main/Auxiliary (Aux) PA role exchange, achieves Doherty-like back-off efficiency enhancement over a 3:1 bandwidth. Distinct from the LMBA PA with a 90° coupler, CCDPA 600a″ and its coupler balun active modulation network can provide differential operation, equal Main/Aux PA weighting, and no inherent early gain compression.

The power amplifier 632a, 632b implements the differential complex neutralization circuit as the level that can provide broadband double-peak gain/reverse isolation improvement. At 60 GHz, the CCDPA 600a″ was observed to achieve 27.3% peak PAE with 21.5 dBm Pₛₐₜ, 22.9% PAE at 19.3 dBm OP_{1 dB}, and 19.1% PAE at 15.5 dBm (6 dB PBO). Overall, the InP CCDPA 600a″ was observed to achieve 18.9-22.6 dBm Pₛₐₜ, 14.7-29.3% peak PAE and 8.2-19.2% 6 dB PBO PAE over 35-100 GHz, showing ×1.08−×1.4/×2.16−×2.86 dB PBO efficiency boost ratio compared to normalized ideal class-B/class-A PA.

With the inclusion of the PA₁/PA₂ devices output capacitances, output pad, and routing parasitics, the exemplary couple balun output network can realize a broadband Iₘ (Z_{12/21})>0 over 42-85 GHz for series Doherty load modulation with PA₁/PA₂ as the Aux/Main PAs. For further low and high frequencies (35-42 GHz and 85-100 GHz) coverage, the output network exhibits Im(Z12/21)<0 (parallel Doherty-like operation) and supports the desired active load modulation by switching PA1/PA2 to Main/Aux PAs, i.e., role-exchange operation.

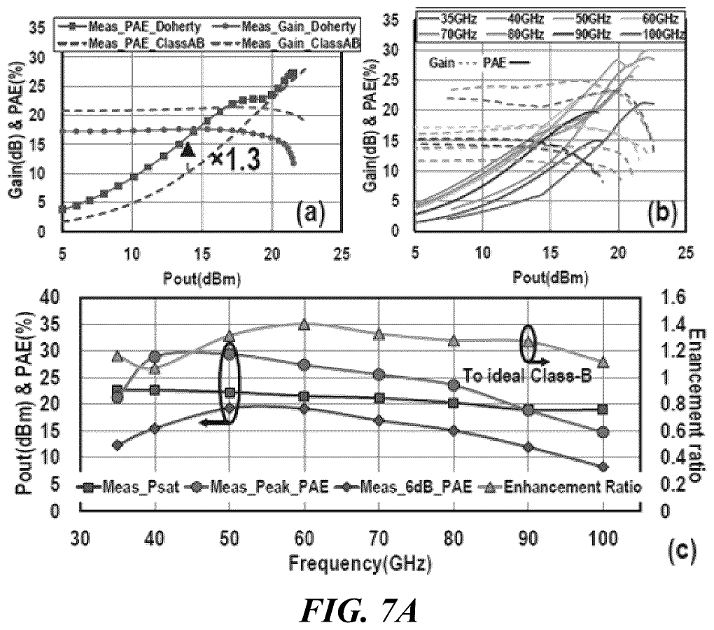

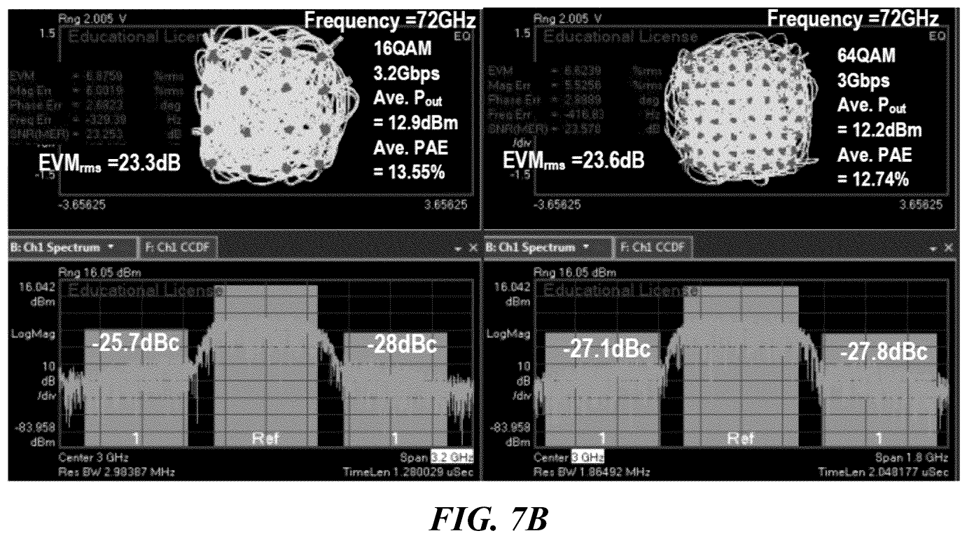

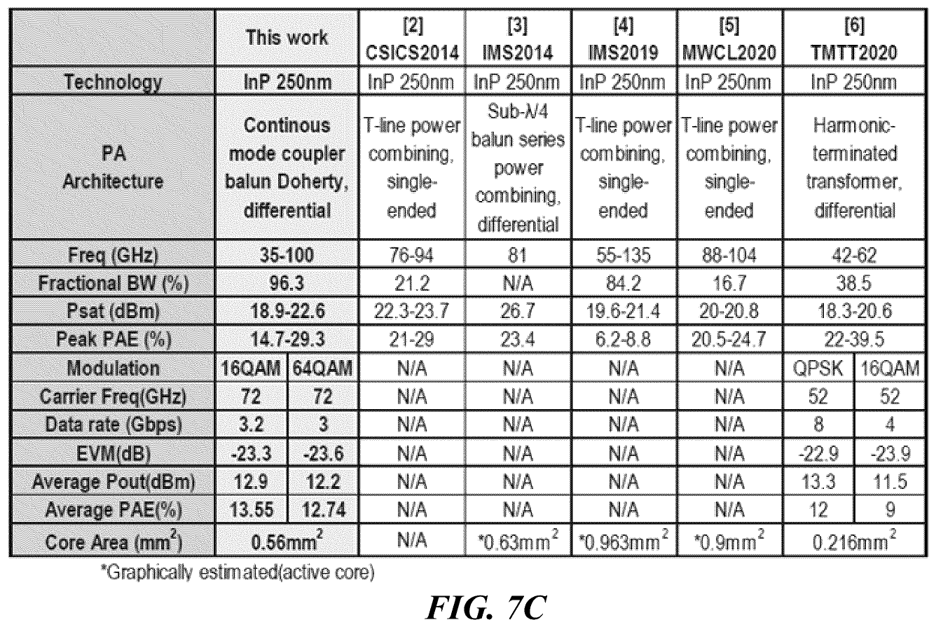

Measured Results. FIGS. 7A-7C show measured results of the CCDPA device 600a″ of FIGS. 6C and 6D. FIG. 7A, subpanes (A) and (B) show the measured CW results. For 35-100 GHz, the CCDPA 600a″ was observed to achieve 18.9-22.6 dBm Pₛₐₜ, 14.7-29.3% peak PAE and 8.2-19.2% 6 dB PBO PAE, verifying the significant PBO bandwidth enhancement. The 6 dB PBO efficiency enhancement ratios over efficiency-normalized idealistic Class-B/A PAs are summarized in FIG. 7A, subpane (C), showing a substantial PBO efficiency boost of ×1.08−×1.4/×2.16−×2.8 from 35 to 100 GHz.

FIG. 7B shows performance measurements of the CCDPA 600a″ using complex modulation test without any DPD. At a 72 GHz carrier frequency, the CCDPA 600a″ demonstrated 3.2 Gbps 16QAM signals with EVMrms/ACPR of −23.3 dB/25.7 dBc with an average Pout/PAE of 12.9 dBm/13.55%.

FIG. 7C shows a table of performance comparison of the CCDPA 600a″ against devices of [2], [3], [4], [5], and [6]. It can be observed that the CCDPA 600a″ has superior wideband high peak/PBO efficiency and outperforms the state-the-of-art wideband InP Pas.

Discussion

The exemplary circuit and device employ a differential complex neutralization scheme for substantial device gain boosting over a wide BW. By exploiting the routing parasitics and mutual couplings, instead of minimizing them, the exemplary device can realize high-order yet compact differential neutralization networks. At high mm-Wave, this high-order feedback attains the Gₘₐₓ>U over a wide BW that can be co-optimized with the device layout to cover the BW of interest. Different from the reported embedding technique, the exemplary device employs a high-order neutralization network that can achieve multiple gain peaks over a wide BW. Overall, the exemplary circuit and device using the high-order complex neutralization scheme can achieve wideband device gain and stability enhancement at high mm-Wave and can support wideband amplifications.

In other embodiments, the exemplary high-frequency mm-wave power amplifier can be employed in stacked active devices. By using a differential complex neutralization feedback network, the stacked active device's broadband power gain and output power can be enhanced while maintaining good reliability.

Additional Discussion. Mm-Wave wireless technologies serve as a key enabler for 5G and beyond-5G revolutions. To maximize the throughput, capacity, and frequency diversity, wireless standards mandate channels with GHz bandwidth (BW) over multiple noncontiguous mm-Wave bands. As high peak-to-average-power-ratio (PAPR) spectrally efficient modulations. e.g., OFDMs, are widely employed, and system dynamic range and linearity are also critical. Moreover, to compensate for the mm-Wave path loss and enable diverse MIMOs, complex high-density arrays with high system energy efficiency are increasingly needed.

These requirements pose tremendous challenges on mm-Wave frontends, in particular power amplifiers (PAs). There is a perennial quest for fundamental innovations on PA topologies [1] that can simultaneously deliver high efficiency (at both peak and back-off PBO) and high linearity over a wide BW.

Besides PA circuit innovations, the PA device process is equally critical. Although GaN/GaAs HEMT devices offer high output power (Pout) with high breakdown voltage, they often exhibit limited power gain at high mm-Wave, and their large layout footprints further complicate designs and integrations. Silicon devices often suffer from low Pout and efficiency due to their limited breakdown voltage and power gain. In contrast, InP device technologies with high fₘₐₓ (>650 GHz), competitive breakdown voltage, and compact footprints are often considered as a promising candidate to implement efficient yet linear mm-Wave/sub-mm-Wave (beyond 5G) frontends [2]-[6].

[14] describes the gain-boosting technique at high mm-wave frequency but with bandwidth limitation. At 260 GHz, this amplifier can only have lower than 10 GHz 3 dB bandwidth, which limits it for the current broadband communication system.

In contrast, the exemplary differential complex neutralization feedback circuitry and operation, as described herein, can overcome these issues. The exemplary device can boost the device gain and also maintain the operation bandwidth by the novel high-order differential neutralization network.

The exemplary circuit can include a 35-100 GHz coupler balun Doherty PA in the Teledyne InP 250 nm HBT process with 650 GHz fₘₐₓ. The PA can employ two design innovations: differential complex neutralization and continuous mode coupler balun Doherty operation. The exemplary PA achieves 18.9-21.5 dBm Psat, 14.7-29.3% peak PAE and 8.2-19.2% 6 dB PBO PAE over 35 to 100 GHz. At 6 dB PBO, the InP PA achieves ×1.08−×1.4/×2.16−×2.8 PAE improvement over the ideal Class-B/A PA back-off behavior over 35-100 GHz, verifying the broadband active load modulation bandwidth. To the authors' best knowledge, this is the first demonstration of active load modulation PA with a 3:1 bandwidth simultaneously over Ka-, V-, and W-bands.

Yet Additional Discussion. Sub-terahertz (sub-THz) electronics are gaining a rapidly increasing interest due to their potential as key enablers for the next-generation 6G wireless revolution. In particular, the D-band 110-170 GHz offers low atmospheric attenuation and massive available bandwidth to support the capacity and latency demands in 6G [1′].

However, a main challenge of D-band electronics is the limited device performance, especially for CMOS devices, to support high intrinsic device power gain at high mm-Wave. The limited intrinsic device gain is a fundamental device challenge at D-band since this frequency is often close to the device's fmax and ft limit that is below 320 GHz for most CMOS/CMOS SOI devices. Further, at high mm-Wave, the passive networks exhibit high passive losses, which degrade the actual circuit-level power gain as well as the circuit output power and efficiency. While new devices are being studied, it is essential to explore circuit techniques that can boost the device gain over a wide band and achieve high-performance D-band frontends using existing device technologies.

The capacitive neutralization, nearly a standard practice now for mm-Wave amplifiers, ideally enhances device gain to U. However, at high mm-Wave, the inevitable parasitic inductances (from metal routings, via stacks, and within the capacitors themselves) become significant and largely degrade the neutralization for the resulting gain, bandwidth, and stability. The Gₘₐₓ embedding in [1′] pushed the device gain to 4U at a single frequency, while the dual peak Gₘₐₓ-core technique in [2′] extended the gain enhancement bandwidth. However, the transistor drain/gate terminals are DC coupled in [1′] and [2′], limiting the amplifiers' biasing choices and performance. [3′] proposed differential complex neutralization for broadband gain with double gain peaks over frequency, which was then employed in an FMCW radar transmitter [4′] but without individual amplifier measurement results. However, these approaches cannot guarantee achieving the maximum device GBW product.

In contrast, the exemplary differential complex neutralization embedding network can boost the gain of the amplifier near the theoretical limits G., 4U for the largest possible bandwidth.

### CONCLUSION

Although example embodiments of the present disclosure are explained in some instances in detail herein, it is to be understood that other embodiments are contemplated. Accordingly, it is not intended that the present disclosure be limited in its scope to the details of construction and arrangement of components set forth in the following description or illustrated in the drawings. The present disclosure is capable of other embodiments and of being practiced or carried out in various ways.

It must also be noted that, as used in the specification and the appended claims, the singular forms “a,” “an,” and “the” include plural referents unless the context clearly dictates otherwise. Ranges may be expressed herein as from “about” or “5 approximately” one particular value and/or to “about” or “approximately” another particular value. When such a range is expressed, other exemplary embodiments include from the one particular value and/or to the other particular value.

By “comprising” or “containing” or “including” is meant that at least the name compound, element, particle, or method step is present in the composition or article or method, but does not exclude the presence of other compounds, materials, particles, method steps, even if the other such compounds, material, particles, method steps have the same function as what is named.

In describing example embodiments, terminology will be resorted to for the sake of clarity. It is intended that each term contemplates its broadest meaning as understood by those skilled in the art and includes all technical equivalents that operate in a similar manner to accomplish a similar purpose. It is also to be understood that the mention of one or more steps of a method does not preclude the presence of additional method steps or intervening method steps between those steps expressly identified. Steps of a method may be performed in a different order than those described herein without departing from the scope of the present disclosure. Similarly, it is also to be understood that the mention of one or more components in a device or system does not preclude the presence of additional components or intervening components between those components expressly identified.

The term “about,” as used herein, means approximately, in the region of, roughly, or around. When the term “about” is used in conjunction with a numerical range, it modifies that range by extending the boundaries above and below the numerical values set forth. In general, the term “about” is used herein to modify a numerical value above and below the stated value by a variance of 10%. In one aspect, the term “about” means plus or minus 10% of the numerical value of the number with which it is being used.

Similarly, numerical ranges recited herein by endpoints include subranges subsumed within that range (e.g., 1 to 5 includes 1-1.5, 1.5-2, 2-2.75, 2.75-3, 3-3.90, 3.90-4, 4-4.24, 4.24-5, 2-5, 3-5, 1-4, and 2-4). It is also to be understood that all numbers and fractions thereof are presumed to be modified by the term “about.”

The following patents, applications, and publications, as listed below and throughout this document, are hereby incorporated by reference in their entirety herein.
[1] H. Wang et al., “Power Amplifiers Performance Survey 2000-Present”.
[2] Z. Griffith, M. Urteaga, P. Rowell and R. Pierson, “A >0 mW SSPA from 76-94 GHz, with Peak 28.9% PAE at 86 GHz,” 2014 IEEE Compound Semiconductor Integrated Circuit Symposium (CSICS), La Jolla, CA, USA, 2014.
[3] H. Park et al., “An 81 GHz, 470 mW, 1.1 mm2 InP HBT power amplifier with 4□1 series power combining using sub-quarter-wavelength baluns,” 2014 IEEE MTT-S International Microwave Symposium (IMS2014), Tampa, FL, USA, 2014.
[4] Z. Griffith, M. Urteaga and P. Rowell, “A 140-GHz 0.25-W PA and a 55-135 GHz 115-135 mW PA, High-Gain, Broadband Power Amplifier MMICs in 250-nm InP HBT,” 2019 IEEE MTT-S International Microwave Symposium (IMS), Boston, MA, USA, 2019.
[5] Z. Griffith, M. Urteaga and P. Rowell, “A $W$-Band SSPA With 100-140-mW Pout, >20% PAE, and 26-30-dB S21 Gain Across 88-104 GHz,” in IEEE Microwave and Wireless Components Letters, vol. 30, no. 2, pp. 189-192, February 2020.
[6] Z. Liu, T. Sharma, C. R. Chappidi, S. Venkatesh, Y. Yu and K. Sengupta, “A 42-62 GHz Transformer-Based Broadband mm-Wave InP PA With Second-Harmonic Waveform Engineering and Enhanced Linearity,” in IEEE Transactions on Microwave Theory and Techniques, vol. 69, no. 1, pp. 756-773, January 2021.
[7] H. Bameri and O. Momeni, “A High-Gain mm-Wave Amplifier Design: An Analytical Approach to Power Gain Boosting,” in IEEE Journal of Solid-State Circuits, vol. 52, no. 2, pp. 357-370, February 2017.
[8] H. Wang, “Fundamentals of RF and Mm-Wave Power Amplifier Designs” 2021 IEEE International Solid-State Circuits Conference—(ISSCC), San Francisco, CA, USA, 2021.
[9] D. J. Shepphard, J. Powell and S. C. Cripps, “An Efficient Broadband Reconfigurable Power Amplifier Using Active Load Modulation,” in IEEE Microwave and Wireless Components Letters, vol. 26, no. 6, pp. 443-445, June 2016.
[10] T. Huang et al., “26.1 A 26-to-60 GHz Continuous Coupler-Doherty Linear Power Amplifier for Over-An-Octave Back-Off Efficiency Enhancement,” 2021 IEEE International Solid-State Circuits Conference—(ISSCC), San Francisco, CA, USA, 2021.
[11] H. T. Nguyen and H. Wang, “A Coupler-Based Differential mm-Wave Doherty Power Amplifier With Impedance Inverting and Scaling Baluns,” in IEEE Journal of Solid-State Circuits, vol. 55, no. 5, pp. 1212-1223, May 2020.
[12] F. Wang and H. Wang, “24.6 An Instantaneously Broadband Ultra-Compact Highly Linear PA with Compensated Distributed-Balun Output Network Achieving >17.8 dBm P1 dB and >36.6% PAEP1 dB over 24 to 40 GHz and Continuously Supporting 64-/256-QAM 5G NR Signals over 24 to 42 GHz,” 2020 IEEE International Solid-State Circuits Conference—(ISSCC), San Francisco, CA, USA, 2020.
[13] N. S. Mannem, M.-Y. Huang, T.-Y. Huang and H. Wang, “A Reconfigurable Hybrid Series/Parallel Doherty Power Amplifier With Antenna VSWR Resilient Performance for MIMO Arrays,” in IEEE Journal of Solid-State Circuits, vol. 55, no. 12, pp. 3335-3348, December 2020.
[14] O. Momeni, “A 260 GHz amplifier with 9.2 dB gain and −3.9 dBm saturated power in 65 nm CMOS,” 2013 IEEE International Solid-State Circuits Conference Digest of Technical Papers, San Francisco, CA, USA, 2013, pp. 140-141, doi: 10.1109/ISSCC.2013.6487672.

### SECOND REFERENCE LIST

[1′] H. Bameri and O. Momeni, “A High-Gain mm-Wave Amplifier Design: An Analytical Approach to Power Gain Boosting,” IEEE J Solid-State Circuits, vol. 52, no. 2.
[2′] D.-W. Park, D. R. Utomo, B. H. Lam, S.-G. Lee, and J.-P. Hong, “A 230-260-GHz Wideband and High-Gain Amplifier in 65-nm CMOS Based on Dual-Peak Gmax-Core,” IEEE J Solid-State Circuits, vol. 54, no. 6.
[3′] T.-Y. Huang, S. Li, N. S. Mannem, and H. Wang, “A 35-100 GHz Continuous Mode Coupler Balun Doherty Power Amplifier with Differential Complex Neutralization in 250 nm InP,” in 2021 IEEE MTT-S International Microwave Symposium (IMS), 2021.
[4′] S. Park et al., “A D-Band Low-Power and High-Efficiency Frequency Multiply-by-9 FMCW Radar Transmitter in 28-nm CMOS,” IEEE J Solid-State Circuits, vol. 57, no. 7.
[5′] N. S. Mannem, T.-Y. Huang, and H. Wang, “Broadband Active Load-Modulation Power Amplification Using Coupled-Line Baluns: A Multifrequency Role-Exchange Coupler Doherty Amplifier Architecture,” IEEE J Solid-State Circuits, vol. 56, no. 10.
[6′] E. Rahimi, F. Bozorgi, and G. Hueber, “A 22 nm FD-SOI CMOS 2-way D-band Power Amplifier Achieving PAE of 7.7% at 9.6 dBm OP1 dB and 3.1% at 6 dB Back-off by Leveraging Adaptive Back-Gate Bias Technique,” in 2022 IEEE Radio Frequency Integrated Circuits Symposium (RFIC), 2022.
[7′] S. Li and G. M. Rebeiz, “High Efficiency D-Band Multiway Power Combined Amplifiers With 17.5-19-dBm Psat and 14.2-12.1% Peak PAE in 45-nm CMOS RFSOI,” IEEE J Solid-State Circuits, vol. 57, no. 5.
[8′] B. Philippe and P. Reynaert, “24.7 A 15 dBm 12.8%-PAE Compact DB and Power Amplifier with Two-Way Power Combining in 16 nm FinFET CMOS,” in 2020 IEEE International Solid-State Circuits Conference—(ISSCC), 2020.
[9′] D. Simic and P. Reynaert, “A 14.8 dBm 20.3 dB Power Amplifier for D-band Applications in 40 nm CMOS,” in 2018 IEEE Radio Frequency Integrated Circuits Symposium (RFIC), 2018.
[10′] U.S. Patent Publication No. 2022/0385254A1.

What is claimed is:

1. An apparatus comprising:
an amplifier core having a differential complex neutralization circuit configured to receive an input signal and generate an output signal having a device gain boosting over a wide bandwidth.

2. The apparatus of claim 1, wherein the differential complex neutralization circuit includes:
a first amplifier having a first terminal, a second terminal, and a third terminal;
a second amplifier having a fourth terminal, a fifth terminal, and a sixth terminal;
a first transmission line coupling the first terminal of the first amplifier to the sixth terminal of the second amplifier through a first neutralization capacitor; and
a second transmission line coupling the fourth terminal of the second amplifier to the third terminal of the first amplifier through a second neutralization capacitor.

3. The apparatus of claim 2, wherein the third terminal of the first amplifier and the sixth terminal of the second amplifier couple to a ground plane through a first and second vias.

4. The apparatus of claim 2, wherein the first terminal of the first amplifier and the fourth terminal of the second amplifier couple to respective power inputs through a third and fourth vias.

6. The apparatus of claim 2, wherein the first neutralization capacitor, the second neutralization capacitor, the first amplifier, and the second amplifier are arranged in parallel orientation to one another.

7. The apparatus of claim 2, wherein the first transmission line and the second transmission line cross-over each other at a point of symmetry in each of the respective first transmission line and the second transmission line.

8. The apparatus of claim 2, wherein the second terminal of the first amplifier and the fifth terminal of the second amplifier are coupled through an embedded transmission line.

9. The apparatus of claim 1 further comprising a second amplifier core that operatively couples to the amplifier core, the second amplifier core having a second differential complex neutralization circuit.

10. The apparatus of claim 1 further comprising a second amplifier core that operatively couples to the amplifier core, the second amplifier core not having the differential complex neutralization circuit.

11. The apparatus of claim 1, further comprising:
a coupler-based matching network that couples to outputs of the differential complex neutralization circuit of the amplifier core.

12. The apparatus of claim 1, further comprising:
a low-loss coupled line (CL) network that couples to outputs of the differential complex neutralization circuit of the amplifier core.

13. The apparatus of claim 1, further comprising:
an adaptive bias circuit configured to dynamically bias gate voltages of amplifier cores of the apparatus based on the input signal.

14. The apparatus of claim 1, wherein the differential complex neutralization circuit is configured in a high-order neutralization network that can achieve multiple gain peaks over a wide BW.

15. The apparatus of claim 1, wherein the apparatus is configured as a power amplifier, a high-frequency amplifier, a low-noise amplifier, or a combination thereof.

16. The apparatus of claim 1, wherein the apparatus is configured as a single-ended amplifier or a differential amplifier.

17. The apparatus of claim 1, wherein the apparatus is employed in a telecommunication system.

18. The apparatus of claim 1, wherein the apparatus is employed in a RADAR system.

19. The apparatus of claim 1, wherein the apparatus is employed in a medical instrument or an electronic test equipment.

20. The apparatus of claim 1, wherein the apparatus is configured as a continuous mode coupler balun Doherty power amplifier.
